(19) United States
(12) Patent Application Publication
(10) Pub. No.: US 2006/0213682 A1
(43) Pub. Date: Sep. 28, 2006

(54) Flexible PCB having surplus bends for electronic equipment

(75) Inventors: Yang Ho Moon, Gyeonggi-do (KR); Se Min Oh, Gyeonggi-do (KR)

Correspondence Address: DARBY & DARBY P.C., P. O. BOX 5257, NEW YORK, NY, 10150-5257, US

(73) Assignee: Samsung Electro-Mechanics Co., Ltd., Gyeonggi-do (KR)

(21) Appl. No.: 11/387,352

(22) Filed: Mar. 22, 2006

(30) Foreign Application Priority Data
Mar. 26, 2005 (KR) 10-2005-0025245

(51) Int. Cl. H05K 1/03

(52) U.S. Cl. 174/255; 174/268

(57) ABSTRACT

A flexible PCB is provided with surplus bends so that it can be readily bent according to the repetitive movement thereof, whereby wires formed in the flexible PCB can be prevented from being severed by the bending fatigue accumulated due to the movement. The flexible PCB for use in electronic equipment acts to transmit electrical signals between two rigid PCBs and acts as a structural bridge therebetween, the two rigid PCBs being spaced away from each other and being able to relatively move. The flexible PCB includes: a plurality of wires, each functioning as a passageway for electrical signals; and a soft material-based substrate body in which the wires are formed; and being provided with surplus bends at predetermined positions so as to allow the flexible PCB to resiliently move according to the relative movement of the rigid PCBs.

### INCORPORATION BY REFERENCE

The present application claims priority under 35 U.S.C. §119 to Korean Patent Application No. 10-2005-0025245 filed on Mar. 26, 2005. The content of the application is incorporated herein by reference in its entirety.

### BACKGROUND OF THE INVENTION

1. Field of the Invention

The present invention relates generally to a flexible PCB for use in electronic equipment. More particularly, the present invention relates to a flexible PCB which is provided with surplus bends so that it can be readily bent according to the repetitive movement thereof, whereby wires formed in the flexible PCB can prevented from being severed by the bending fatigue accumulated due to the movement.

2. Description of the Related Art

With the ability to be readily bent, flexible printed circuit boards (PCBs), most of which are manufactured by patterning copper conductors on polyimide films, are used in electronic equipment, such as printers, mobile phones, etc.

Mobile phones have been developed in structure from an integral form, such as an integral flip-type, to a composite form, such as a folding-type or a sliding-type. Flexible PCBs are not generally applied to flip-type phones, but are applied to folding- or sliding-type phones. In contrast to that of an integral structure in which a display unit, such as an LCD panel, and an input unit, such as a keypad, are relatively fixed in a single case, a mobile phone of a composite structure has relatively position-variable components, such as in a folding-type phone composed of a display part swinging on a hinge and a main body, or in a sliding-type phone composed of a slider and a main body.

In such mobile phones of a composite structure, for example, rigid PCBs are provided for a display unit, such as an LCD panel, and an input unit, such as a keypad, with a flexible PCB connecting them therebetween at a hinge. As such, a flexible PCB structurally connects the two structures provided with their respective rigid PCBs (e.g., display part and main body), as well as functioning as a passage through which electrical signals pass between the two rigid PCBs.

Such a flexible PCB is made of a substrate which can be relatively readily bent, with the opposite termini fixed to the rigid PCBs. According to the relative movement of the rigid PCBs, the flexible PCB has its parts, e.g., adjacent to the opposite termini, severed due to stress-accumulated bending fatigue.

FIG. 1 shows an example in which a conventional flexible PCB is used, with a terminus connecting to a rigid TFT (thin film transistor) substrate, in a cross sectional view.

As shown in FIG. 1, a rigid material-based TFT glass substrate 20, to which a color filter glass substrate 22 is attached, is connected to a flexible PCB 10, with an ACF (anisotropic conductive film) 24 intermediating therebetween. The flexible PCB 10 includes a polyimide tape 12 on which a wire 14 is patterned. A solder resist 16 is formed on the same side of the flexible PCB 10 as on the ACF 24. On the opposite side of the flexible PCB 10 is formed an additional resin layer 26 to prevent the wire from being severed.

In this regard, the solder resist 16 is spaced away from the glass substrate 20 at a predetermined length (a) and overlaps with the resin layer 26 at a predetermined length (L). In such a structure, a severed wire can be prevented by blocking the concentration of stress between the end of the rigid glass substrate 20 and the end of the solder resist 16 of the flexible PCB 10 when bending the flexible PCB 10.

This structure is characterized in that the additional resin layer is formed on the adhesive side (AFC-attached side) of the flexible PCB, thereby preventing the wire 14 from being severed.

In a mobile phone of the composite structure, the flexible PCB experiences more serious bending fatigue because the relative movement (swinging on a hinge) between a display part having an LCD panel, and a main body having a keypad occurs more frequently and the swinging range is larger.

For example, a flexible PCB employed in a folding-type mobile phone, as shown in FIG. 2, may have stress concentrated on the opposite ends thereof and at its parts which are in contact with other structures, thereby undergoing a severing of wires due to the resultant bending fatigue.

In FIG. 2, a conventional flexible PCB 30 connects a first rigid PCB 50 mounted in a structure such as a display part with a second rigid PCB 60 mounted in a structure such as a main body. The first rigid PCB 50 includes a window 54 at which an LCD panel is installed, and a substrate body 52 which is provided with a connector 56 at one side thereof. Acting as an intermediate substrate connecting to a main substrate (not shown) in the main body, the second rigid PCB 60 includes a substrate body 62 on which terminals 64 for communicating with the main substrate, and a connector 66 for communicating with the flexible PCB 30, are formed.

In the flexible PCB 30 the opposite termini of which the two rigid PCBs 50 and 60 are connected, a wire cut is apt to occur at the portions on which stress is concentrated (e.g., A, B, C).

### SUMMARY OF THE INVENTION

Accordingly, the present invention has been made keeping in mind the above problems occurring in the prior art, and an object of the present invention is to provide a flexible PCB which can be used as an connection between two rigid PCBs that move relative to each other, for a long period of time without causing wires formed therein to be severed by the bending fatigue accumulated due to the relative movement.

Another object of the present invention is to provide a flexible PCB which has excellent durability against bending fatigue and can improve the quality of the electronic appliance, such as mobile phones, digital cameras, camcorders, etc., to which it is applied.

In order to accomplish the above object, the present invention provides a flexible PCB for use in electronic equipment which acts to transmit electrical signals between two rigid PCBs and acts as a structural bridge therebetween, said two rigid PCBs being spaced away from each other and being able to relatively move, said flexible PCB including: a plurality of wires, each functioning as a passageway for electrical signals; and a soft material-based substrate body in which the wires are formed; and being provided with surplus bends at predetermined positions so as to allow the flexible PCB to resiliently move according to the relative movement of the rigid PCBs.

In the flexible PCB, the predetermined positions are the portions of the substrate body at which stress is concentrated by the relative movement of the rigid PCBs.

The surplus bends are formed in a plural number along the substrate body.

Preferably, at least one of the surplus bends is formed at a position adjacent to the end of the substrate body.

In one aspect of the present invention, the rigid PCBs may be composed of a first PCB having an LCD panel, and a second PCB having a control circuit for controlling signals input to and output from the LCD panel, said first and said second substrate being installed in respective separate structures so as to move relative to each other, with the flexible PCB interposed therebetween.

In the flexible PCB, the surplus bends are formed using a pair of molds having predetermined molding conformation corresponding to the shapes of the surplus bends. In this regard, at least one of the molds is heated when pressing the flexible PCB.

Preferably, the flexible PCB includes a multilayer structure in which a plurality of wire layers is formed, each being encapsulated by soft material-based sub-substrates.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross sectional view showing one conventional flexible PCB;

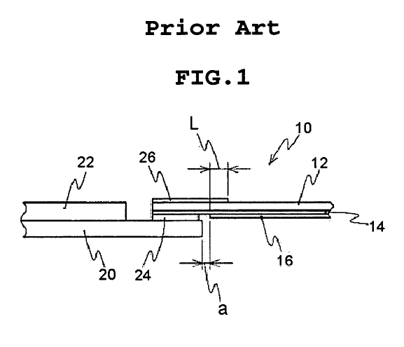

FIG. 2 is a plan view showing another conventional flexible PCB;

FIG. 3 is a plan view showing a flexible PCB in accordance with one embodiment of the present invention;

FIG. 4 is a perspective view of the flexible PCB of FIG. 3;

FIG. 5 is an assembled perspective view of the folding-type mobile phone, with a partially enlarged hinge portion insetted;

FIGS. 6A to 6D are schematic cross sectional views showing a process of forming surplus bends in a flexible PCB in order.

### DESCRIPTION OF THE INVENTION

Reference now should be made to the drawings, in which the same reference numerals are used throughout the different drawings to designate the same or similar components.

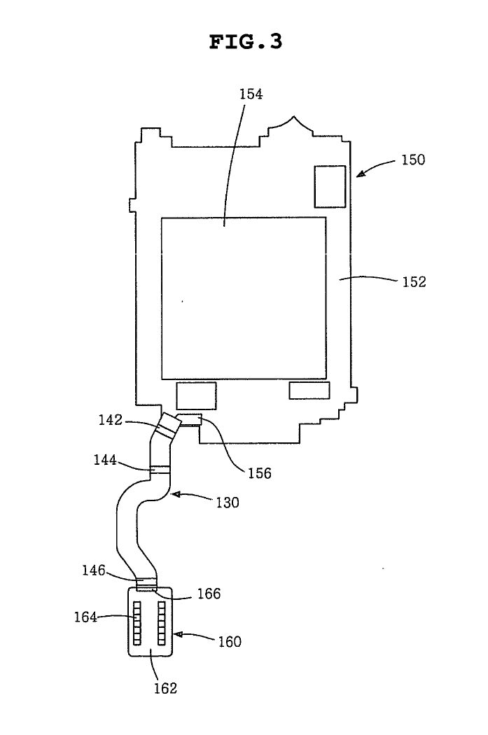

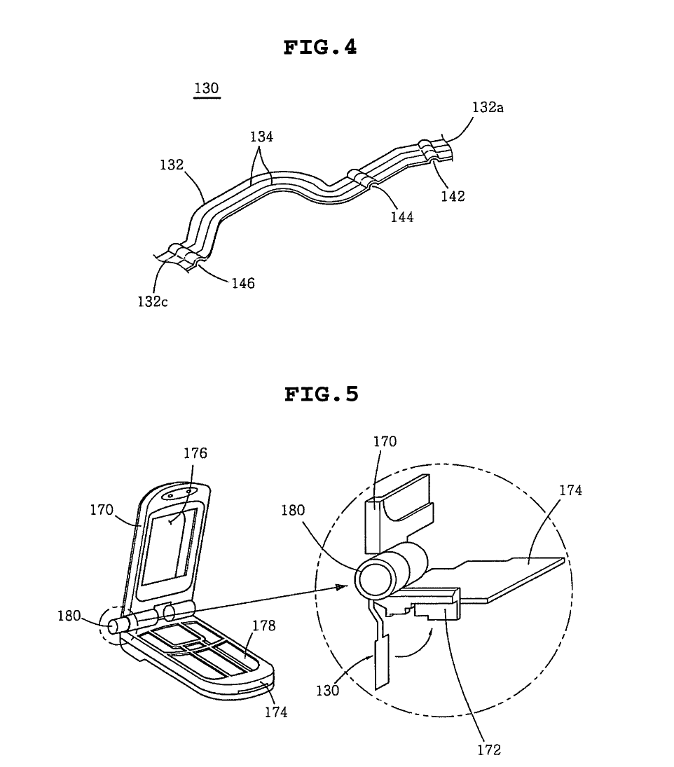

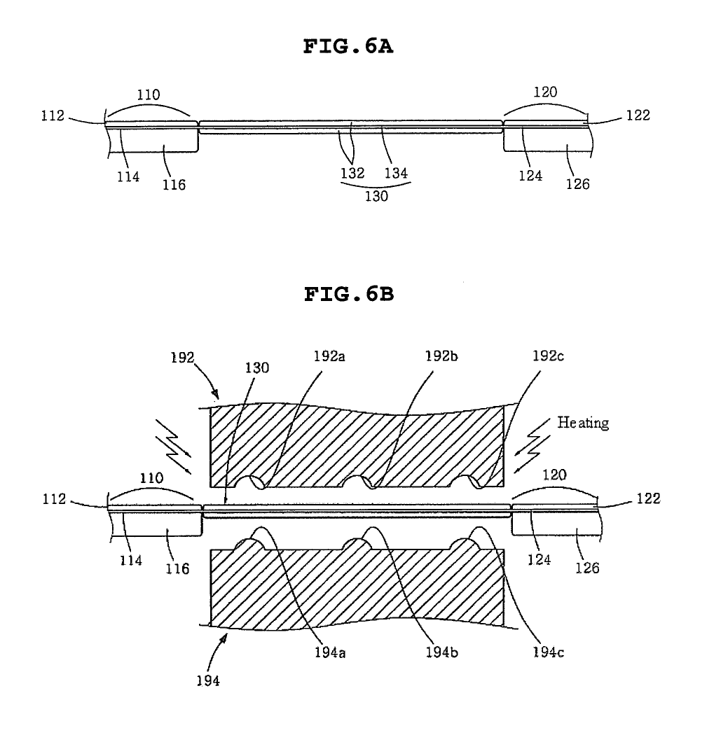

In FIGS. 3 to 5, a flexible PCB in accordance with one embodiment of the present invention and a folding-type mobile phone to which the flexible PCB is applied are shown. FIG. 3 is a schematic partial view of the folding-type mobile phone, FIG. 4 shows the flexible substrate of FIG. 3 in a perspective view, and FIG. 5 is an assembled perspective view of the folding-type mobile phone, with a partially enlarged hinge portion insetted.

As shown in FIGS. 3 and 4, a flexible PCB 130 according to the present invention acts as a bridge between a first PCB 150 mounted in a structure, such as a display part of the folding-type mobile phone, and a second PCB 160 mounted in a structure, such as a main body (not shown) of the folding-type mobile phone. The first PCB 150 includes a window 154 for installing an LCD panel, at a central portion and a substrate body 152 having a connector 156 at one side thereof. The second PCB 160, acting as an intermediating substrate connecting to a main PCB (not shown) in the main body, includes a substrate body 162 on which terminals 164 for communicating with the main substrate and a connector 166 for communicating with the flexible PCB 130 are formed.

It should be noted that the second PCB, although used as an intermediary in this embodiment, is not limited thereto. For example, the main PCB, which is responsible for controlling the transmission and inputting of electrical signals through a keypad in the main body, may be used as the second PCB.

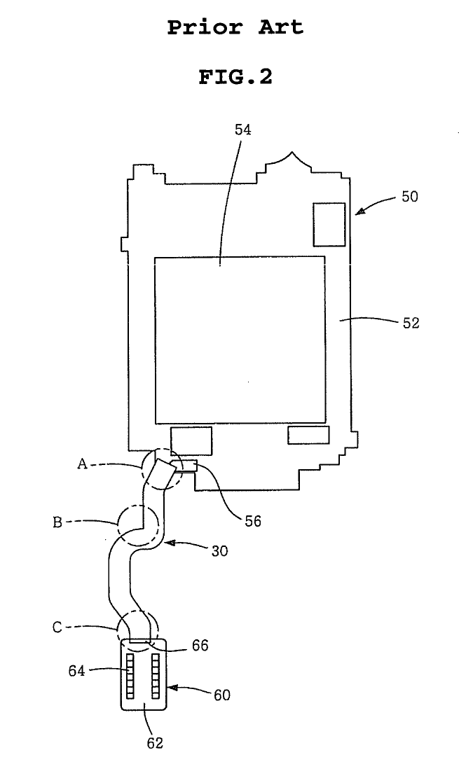

The flexible PCB 130 electrically connects the two rigid PCBs and includes a polyimide film-based substrate body 132 on which Cu wires 134 are formed. This embodiment features surplus bends 142, 144, 146, formed at predetermined positions of a substrate body 132 (for example, portions designated as circles A, B, C in FIG. 2).

When the flexible PCB is bent by a relative movement between the first PCB and the second PCB, these surplus bends 142, 144, 146 play important roles in relieving the stress concentrated thereon.

Referring to FIG. 5, the flexible PCB according to one embodiment of the present invention is assembled into a structure (e.g., folding-type mobile phone). Now a description will be given of the assembly of the flexible PCB into a mobile phone.

The mobile phone shown in FIG. 5 may include a first structure 170 and a second structure 172 in which a first PCB and a second PCB are installed respectively, and a hinge on the base of which the structures are moved relatively (e.g., swing on the hinge), with a flexible PCB 130 electrically connecting the first PCB of the first structure 170 to the second PCB of the second structure 172.

The first structure 170 has a window for an LCD panel while the second structure 172 has a main PCB 174 and windows for key pads. Installed in the second structure 172, the main PCB 174 may be connected to the second PCB, which acts as an intermediate substrate.

In this assembly, the flexible PCB 130 is positioned within the hinge 180, so that it can bend with the swing movement of the display part (the first structure) relative to the main body (the second structure), keeping the electrical connection therebetween.

Like this, the substrate body of the flexible PCB 130 is flexibly bent within such a hinge 180 as is narrow. Accordingly, it is preferred that the flexible PCB 130 of the present invention be provided with surplus bends 142, 144, 146 at the portions to which stress is accumulated upon the movement, e.g., portions adjacent to opposite ends 132a, 132b thereof (portions A and C in FIG. 2) or able to be brought into contact with the hinge (portion B in FIG. 2).

When the substrate body is spread wide after being kept in a bent state, the surplus bends 142, 144, 146 can prevent the concentration of stress on the corresponding portions. In addition, the surplus bends allow the flexible PCB to increase in working range (a length range between the two rigid PCBs in a folded state and a spread state), thereby preventing the danger of contacting the flexible PCB with a structure (e.g., hinge).

The surplus bends according to the present invention do not reside merely in the extension of the flexible PCB. Rather, the flexible PCB of the present invention is structured to maintain a bent form when it is not used (e.g., folded state) and to spread the surplus bends when it is in use (e.g., open state), thereby the extended length can prevent the flexible PCB from contacting the structures.

The flexible PCB of the present invention can be applied to any electronic equipment if it has a structure including two separate rigid PCBs which can move relative to each other. Folding-, rotating- or sliding-type mobile phones, digital cameras and camcorders in which view finders are separated from main bodies, etc., are exemplary. Also, the flexible PCB of the present invention is applicable to all of the electronic appliances which use flexible PCBs in a bending motion, such as printers.

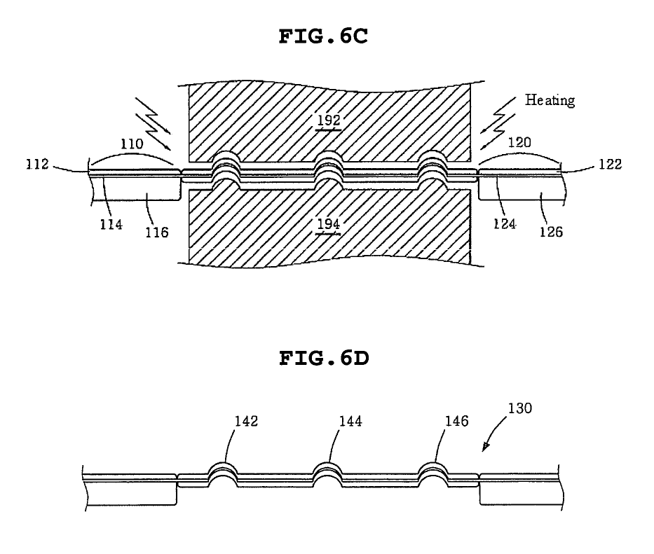

With reference to FIGS. 6A to 6D, a process of forming surplus bends in a flexible PCB will be described in sequential order, below.

FIG. 6A is a cross sectional view of a flexible PCB 130 integrated with rigid PCBs 110, 120. As seen in this view, each of the rigid PCBs 110 and 120 has a structure including a lower substrate 116, 126 and an upper substrate 112, 122, with a wire 114, 124 interposed therebetween. The flexible PCB 130 is composed of a substrate body 132 through which a wire integral with the wires 114, 124 of the rigid PCBs runs. The substrate body 132 of the flexible PCB may be made from polyimide film.

FIG. 6B is a cross sectional view after the integrated flexible PCB 130 are provided between a pair of molds 192, 194 in such a way that the predetermined portions (e.g., A, B, C in FIG. 2) of the flexible PCB correspond to respective pairs of concaves 192a, 192b, 192c and convexes 194a, 194b, 194c of the molds. At least one of the molds is heated so as to readily form the surplus bends.

In the case where molds at room temperature are used to form surplus bends in the flexible PCB, stress is generated in a large quantity and may remain even after processing, degrading the resulting flexible PCB. Preferably, at least one of the molds (the upper mold in the figure) is heated with a heating wire provided therewith.

FIG. 6C is a cross sectional view after the molds are engaged with each other to form surplus bends in the flexible PCB 130.

Finally, FIG. 6D is a cross sectional view after the flexible PCB 130 is drawn out of the molds, with surplus bends 142, 144, 146 formed corresponding to the concaves 192,a, 192b, 192c.

It should be noted that this embodiment, although it is described with regard to the flexible PCB 130 integrated with the rigid PCBs 110, 120, is not intended to limit the present invention. That is, the present invention can be applied for the formation of surplus bends in flexible PCBs separately from the rigid PCBs.

In addition, it should be understood that, although it is not shown in figures, the flexible PCB of the present invention can be formed in such a multilayer structure as it includes wire layers, each being encapsulated by soft material-based sub-substrates. For instance, a flexible PCB consisting of laminated sub-substrate layers is likely to undergo separation into individual sub-substrates due to the residual stress upon the manufacture thereof. The formation of surplus bends in such a multilayer flexible PCB can prevent individual separation, thus improving the assembly property. Furthermore, when a flexible PCB consisting of a plurality of sub-substrates is used repeatedly, the individual separation of the sub-substrates can be prevented thanks to the presence of the surplus bends according to the present invention. As a result, the electronic appliance employing the flexible PCB enjoys improved durability.

As described hereinbefore, the present invention features a plurality of surplus bends at predetermined positions of a flexible PCB, thereby preventing wires formed within the flexible PCB from being severed. In addition, the surplus bends can be formed without undergoing unnecessary stress through a thermal press-molding process using heatable molds. Therefore, the present invention enjoys the advantage of improving the quality of the products to which the flexible PCB is applied, as well as increasing the durability of the flexible PCB.

Although the embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A flexible PCB for use in electronic equipment which acts to transmit electrical signals between two rigid PCBs and acts as a structural bridge therebetween, said two rigid PCBs being spaced away from each other and being able to relatively move, said flexible PCB comprising:
a plurality of wires, each functioning as a passageway for electrical signals; and
a soft material-based substrate body in which the wires are formed having surplus bends at predetermined positions to allow the flexible PCB to resiliently move according to the relative movement of the rigid PCBs.

2. The flexible PCB as set forth in claim 1, wherein the predetermined positions are the positions of the substrate body at which stress is concentrated by the relative movement of the rigid PCBs.

3. The flexible PCB as set forth in claim 1, wherein the substrate body has a plurality of the surplus bends.

4. The flexible PCB as set forth in claim 3, wherein at least one of the surplus bends is formed adjacent to an end of the substrate body.

5. The flexible PCB as set forth in claim 1, wherein the rigid PCBs comprises:
a first PCB having an LCD panel;
a second PCB having a control circuit for controlling signals input to and output from the LCD panel;
and wherein said first and said second PCBs being installed in respective separate structures so as to move relative to each other, with the flexible PCB interposed therebetween.

6. The flexible PCB as set forth in claim 1, wherein the surplus bends are formed using a pair of molds having a predetermined molding conformation corresponding to the shapes of the surplus bends.

7. The flexible PCB as set forth in claim 6, wherein at least one of the molds is heated for pressing the flexible PCB.

8. The flexible PCB as set forth in claim 1, wherein the flexible PCB comprises a multilayered structure having a plurality of wire layers encapsulated by soft material-based sub-substrates.
